(19) United States
(12) Patent Application Publication
(10) Pub. No.: US 2024/0027973 A1
(43) Pub. Date: Jan. 25, 2024

(54) Optimization of a Working State of a System

(71) Applicants: Huilin Zhou, Hefei (CN); Weixing Lu, Los Angeles, CA (US)

(72) Inventors: Huilin Zhou, Hefei (CN); Weixing Lu, Los Angeles, CA (US)

(21) Appl. No.: 17/867,401

(22) Filed: Jul. 18, 2022

(51) Int. Cl. G05B 13/02; G06F 17/12

(52) U.S. Cl. CPC G05B 13/024; G06F 17/12

(57) ABSTRACT

A system for optimizing a dynamic system including controllable working units. The system includes a processor of a controller node connected to a plurality of working units; a memory on which are stored machine-readable instructions that when executed by the processor, cause the processor to: acquire real-time response coefficients data from the plurality of the working units associated with corresponding working points, construct a response matrix based on response coefficients data, generate a tangent plane at each of the working points based on the associated working unit response coefficient, and determine an optimal working point in an area adjacent to the working point within the tangent plane for each of the plurality of the working units.

This application generally relates to process optimization, and more particularly, to an automated optimization of a working state of a system.

### BACKGROUND

Automated refrigeration systems are commonly used. The refrigeration systems are essential in industry and home applications as they perform cooling or maintain room temperature at a desired value. A cycle of refrigeration consists of heat exchange, compression and expansion with a refrigerant flowing through the units within the cycle. Each refrigeration system includes several working units. By adjusting the working states of these units, the system will consume different electrical energy and then produce adjustable cooling effects. However, conventional systems do not provide for an automated optimization of these systems in order to solve the optimal working parameters in the vicinity of this work point.

As such, what is needed is an effective solution that may be used for an automated optimization of a system including multiple working units.

### SUMMARY

One example embodiment provides a system that includes a processor and memory, wherein the processor is configured to perform one or more of: acquire real-time response coefficients data from the plurality of the working units associated with corresponding working points, construct a response matrix based on response coefficients data, generate a tangent plane at each of the working points based on the associated working unit response coefficient, and determine an optimal working point in an area adjacent to the working point within the tangent plane for each of the plurality of the working units.

Another example embodiment provides a method that includes one or more of: acquiring real-time response coefficients data from the plurality of the working units associated with corresponding working points, constructing a response matrix based on response coefficients data, generating a tangent plane at each of the working points based on the associated working unit response coefficient, and determining an optimal working point in an area adjacent to the working point within the tangent plane for each of the plurality of the working units.

A further example embodiment provides a non-transitory computer readable medium comprising instructions, that when read by a processor, cause the processor to perform one or more of: acquire real-time response coefficients data from the plurality of the working units associated with corresponding working points, construct a response matrix based on response coefficients data, generate a tangent plane at each of the working points based on the associated working unit response coefficient, and determine an optimal working point in an area adjacent to the working point within the tangent plane for each of the plurality of the working units.

### BRIEF DESCRIPTION OF THE DRAWINGS

FIG. 1 illustrates an example of a dynamic system has n controllable working units, according to example embodiments.

FIG. 2 illustrates an example of a dynamic system such as a refrigeration system that has multiple controllable working units, according to example embodiments.

FIG. 3 illustrates graphic the responses of Δeᵢ, and Δaⱼ when wᵢ is injected a square wave excitation Δwᵢ with a period of T, according to example embodiments.

FIG. 4 illustrates a graph of superimposes small amplitude signals by PWM, according to example embodiments.

FIG. 5 illustrates a diagram of a network used for optimization of a dynamic system, according to example embodiments.

FIG. 6 illustrates a network diagram of a system including a detailed description of an optimization controller node, according to example embodiments.

FIG. 7 illustrates a flow diagram of a method for optimization of a dynamic system, according to example embodiments.

FIG. 8 illustrates a further flow diagram of the method, according to example embodiments.

FIG. 9 illustrates an example controller node that supports one or more of the example embodiments.

### DETAILED DESCRIPTION

It will be readily understood that the instant components, as generally described and illustrated in the figures herein, may be arranged and designed in a wide variety of different configurations. Thus, the following detailed description of the embodiments of at least one of a method, apparatus, non-transitory computer readable medium and system, as represented in the attached figures, is not intended to limit the scope of the application as claimed but is merely representative of selected embodiments.

The instant features, structures, or characteristics as described throughout this specification may be combined or removed in any suitable manner in one or more embodiments. For example, the usage of the phrases “example embodiments”, “some embodiments”, or other similar language, throughout this specification refers to the fact that a particular feature, structure, or characteristic described in connection with the embodiment may be included in at least one embodiment. Thus, appearances of the phrases “example embodiments”, “in some embodiments”, “in other embodiments”, or other similar language, throughout this specification do not necessarily all refer to the same group of embodiments, and the described features, structures, or characteristics may be combined or removed in any suitable manner in one or more embodiments. Further, in the diagrams, any connection between elements can permit one-way and/or two-way communication even if the depicted connection is a one-way or two-way arrow. Also, any device depicted in the drawings can be a different device. For example, if a mobile device is shown sending information, a wired device could also be used to send the information.

In addition, while the term “message” may have been used in the description of embodiments, the application may be applied to many types of networks and data. Furthermore, while certain types of connections, messages, and signaling may be depicted in exemplary embodiments, the application is not limited to a certain type of connection, message, and signaling.

Example embodiments provide methods, systems, components, non-transitory computer readable media, devices, and/or networks, which provide for an automated optimization of a working state of a system.

The example embodiments provide for optimization of a dynamic system composed of multiple work units. A response matrix is constructed by superimposing periodic excitations of the system at the input and detecting its output in real time. Based on the response matrix, linear programming is used to solve the optimal working parameters in the vicinity of this work point. The optimal working state can be iteratively approached step-by-step.

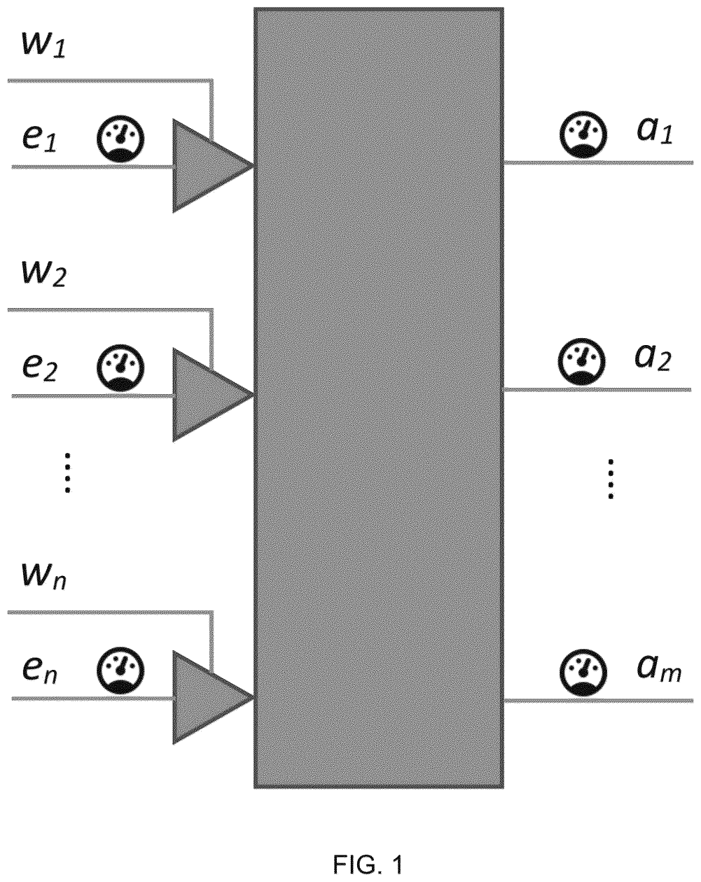

As shown in FIG. 1, the dynamic system has n controllable working units. By adjusting the working states wᵢ (i=1, 2, . . . n) of these working units, the output states aⱼ (j=1, 2, . . . m) can be changed to achieve m groups of set goals Aⱼ (j=1, 2, . . . m).

The working unit may consume resources eᵢ (i=1, 2 . . . n) such as water, electricity, gas, fuel, cooling, or heat energy, etc. and conduct energy conversion and transmission to achieve the set goals as output.

Here, wᵢ is the control variable, eᵢ and aⱼ are dependent variables that are functions of wᵢ and can be collected in real time. There may be multiple resource consumption eᵢ of the working unit of a dynamic system. Different types of resources should be normalized into a unified unit (U). For instance, if the goal is an efficient operation (i.e., saving money), it should be normalized into a monetary unit; if the goals is reducing carbon emission, it should be normalized into carbon emission units.

However, each component of set goals can be in different units. For example, the output requirements of a system are: (a) the temperature (T) of the water tank is constant at 20° C.; (b) the output water flow is 1 m³/min. Two units involved here are T° C. and m³/min respectively. The basic task of the dynamic system optimization is to select a set of wᵢ to minimize the consumed resources Σeᵢ under the condition of satisfying the set goals Aⱼ.

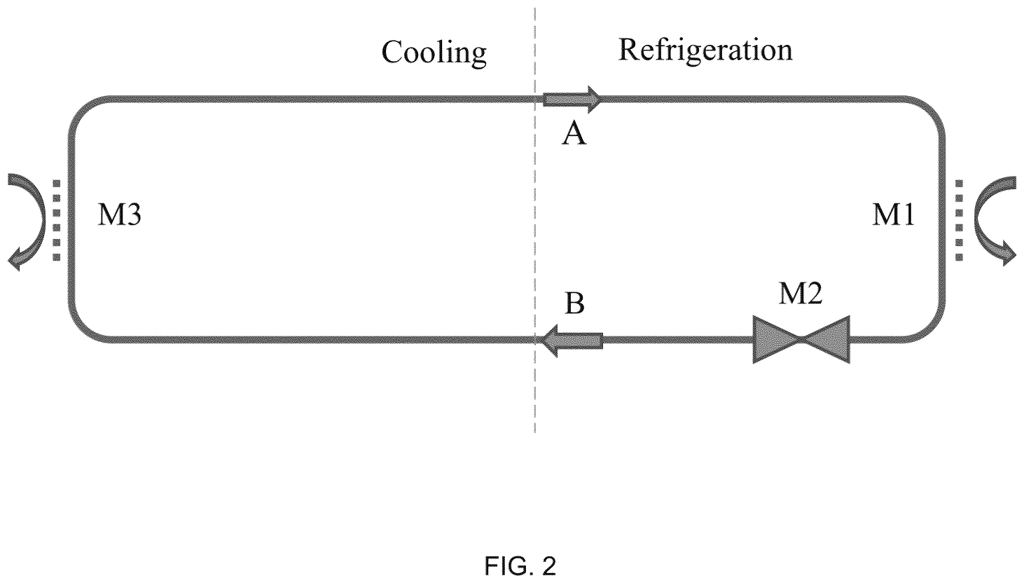

FIG. 2 illustrates an example of a dynamic system such as a refrigeration system that has n controllable working units. The refrigeration system may be simplified into a structure depicted in FIG. 2, in which the left half is the cooling process. During the cooling process, the cooling capacity is introduced into the cooling pipe (M3) through cooling medium flow pumped by M2, and then the cooling capacity is finally delivered into the application space through the supply air flow. The right half is the refrigeration process, during which the heat is exchanged to the outside (M1) and cold flow is returned (M2).

M1, M2, and M3 represent the working units of the refrigeration system. As discussed above, by adjusting their working states wᵢ, the system will consume different electrical energy eᵢ and then produce adjustable cooling effects aⱼ. For the refrigeration element M1, the higher the return temperature (i.e., the temperature at point A) and the flow rate (the pumping speed of M2) are, the higher the efficiency of its heat dissipation to the outside (more cooling capacity per unit energy consumption) is.

For the conveying element M2, the smaller the output flow rate is, the smaller the resistance loss is, and then the higher the conveying efficiency (the flow rate conveyed per unit of energy consumption) is. For the cooling element M3, the lower the temperature of the refrigerant (i.e., the temperature at point B) is, the more efficiently the cooling capacity can be delivered to the room. For such a system, the disclosed embodiments intend to solve the following problems:

For the set cooling demand:
who will contribute more to M1, M2, and M3; and
who will contribute less, so that the power consumption can be minimized.

The resource consumption and output of the working unit are related to its working state. Adjusting the working state of the working unit will change the resource consumption and output of the working unit, and ultimately affect the output of the system. Since the system is composed of multiple working units and each working unit has a different working efficiency and different influences on different output parameters, the system needs to be optimized to identify which unit should have more working output and which unit should have less working output.

In the exemplary embodiments, the entire dynamic system is regarded as a black box, and the working state of its working unit is adjusted to minimize resource consumption while ensuring that each output parameter conforms to the set goals. Suppose there are m outputs that are a₁, a₂ . . . aₘ and satisfy the set goals A₁, A₂ . . . Aₘ respectively in the system. Assuming that there are n working units in the system with the working states are w₁, w₂ . . . wₙ, and their resource consumptions are e₁, e₂ . . . eₙ. The resource consumption of each working unit is:

eᵢ=fᵢ(wᵢ) (1)

Where i=1,2 . . . n, and f is the energy consumption function of the iₜₕ working unit.

Total system resource consumption:

$$E = {\sum }_{i = 1}^{n} {e}_{i} \qquad ( 2 )$$

Assuming that the change of the iₜₕ working unit causes the change of the jₜₕ output to be:

Δa_{i,j}=r_{i,j}(w₁,w₂ . . . wₙ)×Δwᵢ

Then, the change of all working units causes the change of the jₜₕ output to be:

$$Δ {a}_{j} = {\sum }_{i = 1}^{n} {r}_{i , j} ( {w}_{1} , {w}_{2} , … , {w}_{n} ) \times Δ {w}_{i} \qquad ( 3 )$$

Among them, r_{i,j} is the response function, and its value is equivalent to the slope (partial derivative, ∂aⱼ/∂wᵢ) of the aⱼ-wᵢ curve at the working point, which represents the influence on the output aⱼ when the working state wᵢ changes slightly. If there is a linear relationship between the working state of the working unit and the output, the above response function degenerates into a constant—so called the response coefficient c_{i,j}. In this case, the relationship between the output and resource consumption is as follows:

$${a}_{j} = {\sum }_{i = 1}^{n} {c}_{i , j} \times {w}_{i} + {c}_{j} \qquad ( 4 )$$

where cⱼ is a constant.

Under this linear condition, the optimal solution of the system operation can be reduced to the solution of the linear function group. In practice, there is no linear relationship between eᵢ and wᵢ, and between aⱼ and wᵢ, so there is no any fixed response matrix that applies to the entire input range and life cycle. But in the vicinity of each operating point, it can be processed linearly, and its response coefficients can be measured separately to calculate the trend of the optimal operating parameters there.

The relationship between the output parameter and the working status near the work point is expressed as follows:

$$\{ \begin{matrix}Δ {a}_{1} = {c}_{1 , 1} \times Δ {w}_{1} + {c}_{2 , 1} \times Δ {w}_{2} + … + {c}_{n , 1} \times Δ {w}_{n} \\ Δ {a}_{2} = {c}_{1 , 2} \times Δ {w}_{1} + {c}_{2 , 2} \times Δ {w}_{2} + … + {c}_{n , 2} \times Δ {w}_{n} \\ … \\ Δ {a}_{m} = {c}_{1 , m} \times Δ {w}_{1} + {c}_{2 , m} \times Δ {w}_{2} + … + {c}_{n , m} \times Δ {w}_{n}\end{matrix} \qquad ( 5 )$$

or expressed in matrix operations:

$$\vert \begin{matrix}Δ {a}_{1} \\ … \\ Δ {a}_{m}\end{matrix} \vert = \vert \begin{matrix}{c}_{1 , 1} & … & {c}_{n , 1} \\ … & … & … \\ {c}_{1 , m} & … & {c}_{n , m}\end{matrix} \vert \vert \begin{matrix}Δ {w}_{1} \\ … \\ Δ {w}_{n}\end{matrix} \vert \qquad ( 6 )$$

The above matrix |c_{i,j}| is called the response matrix. For the dynamic system, the

following optimization strategy can be implemented: at the current working point (w₁ . . . wₙ), detecting the response coefficients of each working unit to form a response matrix, calculating the adjacent better working parameters according to the response matrix, and adjusting the system operation according to the working parameters to make the work at a better working point. The above process is iterated to make the working parameters slipping to the optimum working point, and finally stabilize at the optimum working point. There are two key steps here: A—the detection of the response coefficient, and B—the optimization algorithm.

Since the step iteration is used here, the evaluation function E(wᵢ) is required to be a concave or a convex function, so as to ensure that the optimal value of the approximation applies to the entire range. Most of the dynamic systems meet this requirement.

According to the exemplary embodiments, the response matrix consists of a series of response coefficients, which can be detected in real time. If the iₜₕ working unit is in the working state wᵢ, the excitation with the amplitude of Δwᵢ (for example, Δwᵢ=10%) and the period of T superimposed at its working point position is:

wᵢ(t)=wᵢ+Δwᵢ×cos(2πt/T) (7)

At this point, the resource consumption eᵢ will respond:

eᵢ(t)=eᵢ+Δeᵢ×cos(2πt/T-ϕₑᵢ) (8)

where ϕₑᵢ is the phase lag.

Likewise, some or all of the output parameters a₁, a₂ . . . aₘ will respond:

aⱼ(t)=aⱼ+Δaⱼ×cos(2πt/T-ϕₐⱼ) (9)

where ϕₐⱼ is the phase lag.

Define ρᵢ as the response coefficient of the energy consumption at the working status wᵢ relative to the working intensity, then:

ρᵢ=Δeᵢ/Δwᵢ (10)

Define c_{i,1}, c_{i,2} . . . c_{i,m} as the response coefficient of the goal parameter relative to the working intensity, then:

c_{i,j}=Δaⱼ/Δwᵢ (11)

where c_{i,j} is the response coefficient of the aforementioned response matrix.

While injecting the excitation signal, synchronously collect eᵢ and a₁, a₂ . . . aₘ at a sampling frequency not less than 4 times (sampling frequency f=2⁽²⁺ⁱ⁾(1/T), i=0, 1, 2 . . . ), and then analyze the collected data series with the FFT spectrum analysis. Calculate the amplitudes of eᵢ and a₁, a₂ . . . aₘ at the corresponding frequency (1/T) respectively, and then the calculated amplitudes are Δeᵢ and Δaⱼ. After Δeᵢ and Δaⱼ divided by Δwᵢ, ρᵢ and c_{i,1}, c_{i,2} . . . c_{i,m}, et al can be obtained.

In the same way, each working element iϵ[1, n] is excited, collected and calculated respectively, and then all the response coefficients ρ and c can be obtained. In practice, wᵢ is usually an integer in a range (such as between 0 and 100), and its resolution is limited, and its small change Δwᵢ has even lower resolution, and so it is rather impossible to synthesize an ideal triangular waveform by changing its value. In practice, square wave excitation is employed instead of an ideal triangular waveform. Since the Fourier expansion of the square wave has harmonic components, the processing result only takes its fundamental frequency component.

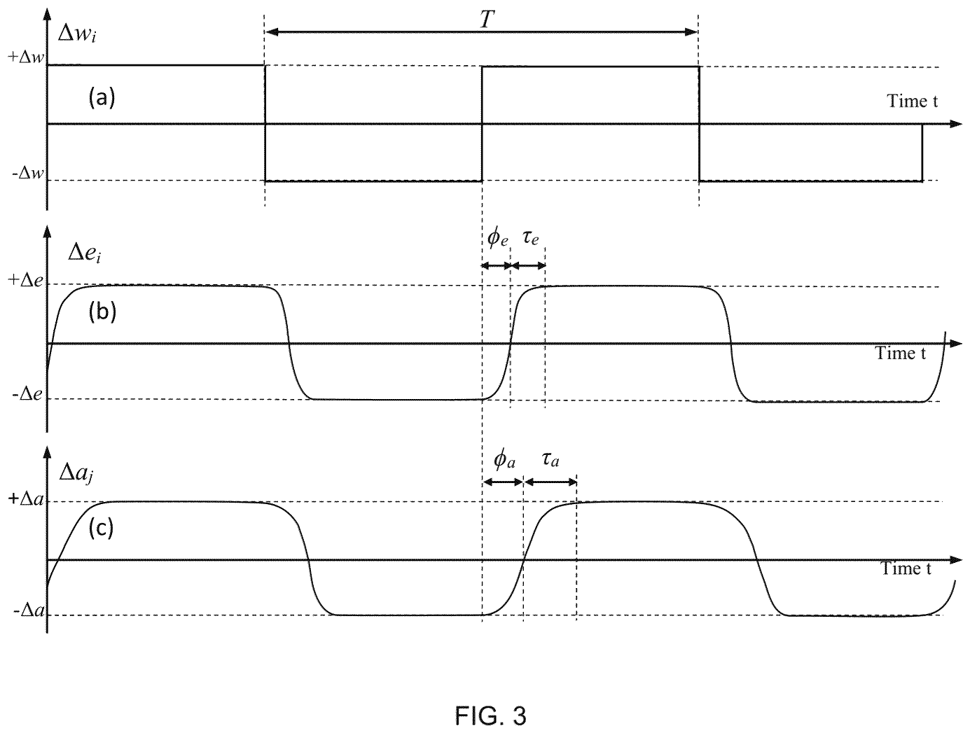

FIG. 3 shows the responses of Δeᵢ and Δaⱼ when wᵢ is injected a square wave excitation Δwᵢ with a period of T. In order to clearly express relation between the excitation and response, the aperiodic components in equations (7)-(9) are not shown in FIG. 3, such as wᵢ, eᵢ, aⱼ, these aperiodic components are filtered out in the FFT process.

The parameter ϕ in FIG. 3 is the phase difference between the response and the excitation, reflecting the response lag; the parameter τ is the response time (climbing time), if the excitation period T<4τ, the response curve will not reach the peak (the maximum value of steady state), and the calculated response coefficient will be less than true value. In this range, the smaller the excitation period is, the smaller the calculated response coefficient will be. Therefore, taking T>=4τ can obtain more accurate results.

As discussed above, in the range of T<4τ, the calculated response coefficient increases monotonically with T Using this phenomenon, the minimum value of T can be determined: starting from a given smaller period T₀ and increasing by 2 times each time (T×2^{°}, T×2¹, . . . T×2ⁱ), detecting response coefficients r₀, r₁, . . . rᵢ, when (rᵢrᵢ₋₁)/rᵢ<0.05, then T=T₀×2ⁱ can be used as the minimum excitation period. Of course, if the cycle is too small, the system will have no response. At this time, the comparison between rᵢ and rᵢ₊₁ is meaningless. It is also possible to start from a long cycle, and advance to a short cycle according to the law of halving the cycle to obtain its minimum excitation cycle. Both methods can be used in practice.

If a system consists of n work units, it will take a long time to detect the response coefficients one by one. Therefore, multiple work units should be tested at the same time. At the same time, different frequency excitations are applied to different work units. After FFT analysis, the amplitudes at these frequencies correspond to the response coefficients of this group of work units. The frequencies of this group of excitation signals should be co-prime, so that the harmonic components of the low-frequency signal cannot be superimposed on the high-frequency response. For example, if a square wave excitation of 2 Hz and 4 Hz is applied at the same time, the response of the latter will contain a small amount of frequency-octave response components of the former, thus affecting the accuracy of the measurement.

The period time T of the response frequency of the dynamic system is possible from seconds to minutes. For example, in a car engine, the throttle control to the motor response only takes milliseconds and it takes a few seconds to accelerate (decelerate) to the steady speed for the vehicle. However, it may take an order of a few tens of seconds for the air conditioning system to increase from the increase of power to the improvement of cooling to a new steady state. It is due to the response lag that after each cycle of testing is over the maximum lag time for the next round of measurements should be waited to ensure that the full response cycle of the previous test has ended.

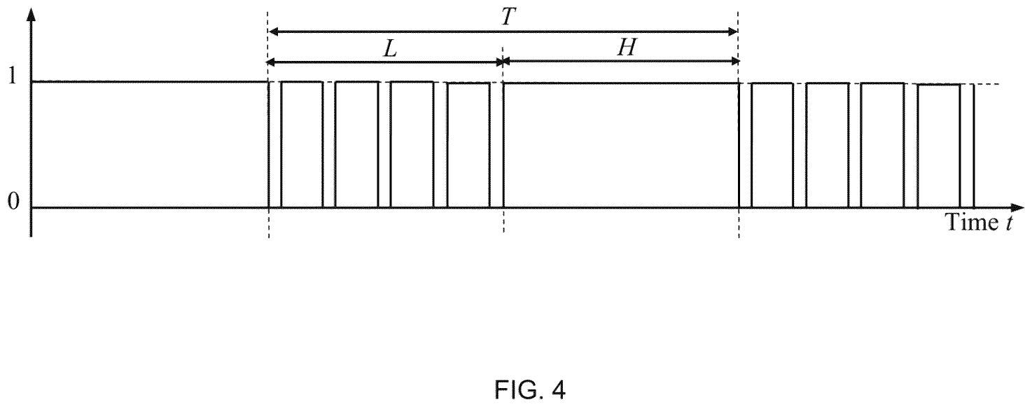

FIG. 4 illustrates superimposes small amplitude signals by PWM. The above-mentioned periodic small-amplitude signal Δwᵢ, if wᵢ has a good resolution it can be directly realized by amplitude modulation (AM). However, the working state wᵢ of some work units is not continuously adjustable, and may only have two states of “on” and “off”, which can only take the values “0” and “1”. At this time, the PWM method can be used to periodically change its duty cycle to superimpose periodic excitation, as shown in FIG. 4. In FIG. 4, T is the excitation period, the duty cycle of the L section is small, and the duty cycle of the H section is relatively large (100% in the figure). Obviously, the total output of the L section is smaller than that of the H section. By adjusting the duty cycle, the continuously adjustable output of wᵢ can be realized.

Linear Programming in accordance with the exemplary embodiments is implemented as follows. The response matrix expresses the response status of the area adjacent to the working point. In this interval, the optimal working parameters are obtained through linear programming, and then the response matrix is constructed at the new working point to obtain the new optimal working parameters, successive iterative approximations. For the convenience of discussion, the working state wᵢ is first normalized to [0-1], and then the decision variable Δwᵢ is linearly programmed in the vicinity of the working point.

Assume that the optimization goal is to minimize the total resource consumption, that is:

Minimize: E=ρ₁w₁+ρ₂w₂+ . . . +ρₙwₙ (12)

Assuming that wᵢ^{(k)} is the working state of the kth iteration, wᵢ^{(k+1)} is the working state of the k+1th iteration, and Δwᵢ^{(k+1)} is the decision variable of the k+1th iteration, then:

wᵢ^{(k+1)}=wᵢ^{k}+Δwᵢ^{k+1} (13)

Substitute (13) into (12) and replace wᵢ with wᵢ^{(k+1)} to get the objective function:

$$Minimize : E = {\sum }_{j = 1}^{n} {ρ}_{i} \times Δ {w}_{i}^{( k + 1 )} + {\sum }_{i = 1}^{n} {ρ}_{i} \times {w}_{i}^{k}$$

For objective functions such as min and max, the constant term can be omitted, so the second term on the right side of the equation can be omitted. At the same time, this formula has nothing to do with the number of iterations (k+1) and can also be omitted, thus it simplifies as follows:

$$Minimize : E = {\sum }_{i = 1}^{n} {ρ}_{i} \times Δ {w}_{i} \qquad ( 14 )$$

The above formula is the objective function of linear programming in the vicinity of the working point. The constraints are divided into two parts: firstly, the output parameters shown in formula (5) should meet the “set goal” and “Set goal” can be understood as the “output” ≤, = or ≥ a certain value. Note that ≥ is taken only as an example; secondly, the working state Δwᵢ should be constrained in the effective region. Assuming that the set goals is that the output value aⱼ is not less than Aⱼ, let aⱼ^{(k)} be the output value of the kth iteration, and Δaⱼ^{(k+1)} be the change of the output value caused by the k+1th iteration, then Δaⱼ^{(k+1)} should satisfy:

aⱼ^{k}+Δaⱼ^{(k+1)≥A}ⱼ

Thereby

Δaⱼ^{(k+1)}≥Aⱼ-aⱼ^{k} (15)

Let ΔAⱼ=Aⱼ-aⱼ^{k}, Δwᵢ=Δwᵢ^{(k+1)}, according to formula (5), the constraints of the k+1th iteration can be written as:

$$\{ \begin{matrix}{c}_{1 , 1} \times Δ {w}_{1} + {c}_{2 , 1} \times Δ {w}_{2} + … + {c}_{n , 1} \times Δ {w}_{n} \geq Δ {A}_{1} \\ {c}_{1 , 2} \times Δ {w}_{1} + {c}_{2 , 2} \times Δ {w}_{2} + … + {c}_{n , 2} \times Δ {w}_{n} \geq Δ {A}_{2} \\ … \\ {c}_{1 , m} \times Δ {w}_{1} + {c}_{2 , m} \times Δ {w}_{2} + … + {c}_{n , m} \times Δ {w}_{n} \geq Δ {A}_{m}\end{matrix} \qquad ( 16 )$$

This linear programming is to find the next best working point in the tangent plane of the current working point. If the step is too large, the tangent plane will obviously deviate from the actual working curved surface. Therefore, the above Δwᵢ should be constrained to a small region [δ/2, δ/2], δ is a selected small amount (such as 0.1, 0.2 . . . ), and to ensure that wᵢ is in between [0-1], Δwᵢ should meet additional constraints. Considering that two consecutive iterations satisfy:

wᵢ^{(k+1)}=wᵢ^{(k)}+Δwᵢ^{(k+1)} (17)

The variation range of Δwᵢ is constrained as follows:

$$( 18 )$$

$$\{ \begin{matrix}1. If {w}_{i}^{( k )} \geq δ / 2 and {w}_{i}^{( k )} \leq 1 - δ / 2 , that is , {w}_{i}^{( k )} is far from \\ the boundary , then : \\ Δ {w}_{i} ∈ [ - δ / 2 , δ / 2 ; \\ 2. If {w}_{i}^{( k )} < δ / 2 , that is , {w}_{i}^{( k )} is closer to the lower \\ boundary , then : \\ Δ {w}_{1} ∈ [ - {w}_{i}^{( k )} , δ / 2 ] ; \\ 3. If {w}_{i}^{( k )} > 1 - δ / 2 , that is , Δ {w}_{i} is closer to the upper \\ boundary , then : \\ Δ {w}_{i} ∈ δ / 2 , 1 - {w}_{i}^{( k )} ]\end{matrix}$$

According to (14) (16) (18) linear programming operations can be performed. Such linear programming solution process is no longer discussed here because it has been widely used and can be found in commercial and open-source solution processes.

In one embodiment, an Optimal Control is implemented as follows. An iterative method is used to gradually transfer from the initial state to the optimal state. Denote the feasible region of the working state as Rⁿ, and iterate from a selected initial state w⁽⁰⁾ϵRⁿ. Let the working state w^{(k)} be the k-th iteration point, detect its resource consumption E^{(k)} and its response matrix c^{(k)}, and obtain the optimal state w^{(k+1)} in its neighborhood by linear programming, as the iteration point of the k+1 round; adjust the actual working state to w^{(k+1)}, check its resource consumption E^{(k+1)}, and end if the termination condition is satisfied, otherwise, check its response matrix, and carry out next iteration.

The above vector Δw^{(k+1)}=w^{(k+1)}-w^{(k)} is a step vector, and its vector direction is the resource consumption decline direction, and its modulus is the step size. For w^{(k+1)}, its effectiveness needs to be evaluated: A. If the linear programming has no solution at w^{(k+1)}, it means that w^{(k+1)} has deviated from the feasible region; B. If the objective function value changes in the opposite direction (E^{(k+1)}>E^{(k)}), indicating that w^{(k)} has passed the optimal point. In either case, take δₙₑₓₜ=δₚᵣₑᵥ×0.618, go back two steps, start from w^{(k+1)}, and iterate in smaller steps until the termination condition is met.

There are two termination conditions:

A. The difference between the objective functions of two consecutive working states is less than the set value:

E^{(k+1)}-E^{(k)}_{<σ}

where σ is a set constant, such as 0.0001.

B. The step size between two consecutive working states is less than the set value:

|w^{(k+1)}-w^{(k)}|<λ

where λ is a set constant, such as 0.00001.

The above-mentioned iterative process must be accompanied by the process of reducing δ, and the process of gradually reducing δ can effectively avoid jumping on both sides of the optimal working state and falling into the dilemma of an infinite loop (“seesaw” phenomenon). This iterative process is similar to the Frank-Wolfe Algorithm.

According to one embodiment, Simulation Verification is provided. The refrigeration system depicted in FIG. 2 is used as the basic prototype to verify its iterative convergence process. Assume that the working states of the three working units M1, M2, and M3 are w₁, w₂, and w₃, respectively, and the value range is [0-1]. It is assumed that the unit resource consumption is linearly related to the unit working state:

eᵢ=ρᵢwᵢ, (i=1,2,3)

The objective function is to minimize the total resource consumption, namely:

Minimize: E=ρ₁w₁+ρ₂w₂+ρ₃w₃

ρ₁, ρ₂, ρ₃ are given constants, without loss of generality, take ρ₁=1, ρ₂=2, ρ₃=3, then:

Minimize: E=w₁+2×w₂+3×w₃ (19)

It is assumed that the cooling capacity a₁ has a nonlinear relationship with the working state:

a₁=w₁×w₂×w₃−0.4×w₁²×w₂²×w₃² (20)

The above coefficient (0.4) is an arbitrary constant, but it is ensured that the inflection point of the quadratic function is outside the value range [0, 1] of wᵢ. The function has the following characteristics:
1. If any unit i stops working (that is, wᵢ is zero), the overall output is zero;
2. It is a concave function within the value range of wᵢ;
3. Non-linear, making it more typical. Obviously, when w₁=w₂=w₃=1, a₁ has a maximum output a₁ₘₐₓ=0.6.

The above shows that three working units (M1, M2, M3) cooperate to complete a work target (cooling capacity a₁). To make this verification more general, we add an additional output requirement, such as requiring the M3 to output a certain air volume:

a₂=w₃−0.4w₃² (21)

Obviously, when w₃=1, a₂ has a maximum output of a₂ₘₐₓ=0.6.

The problem now is attributed to: the output cooling capacity is required to be not less than Aland the air volume is not less than A₂, and how to set the values of the working states w₁, w₂, and w₃ to minimize the total resource consumption E.

The above-mentioned linear programming iterative method is used to approximate the optimal working point. Starting from the initial working point w⁽⁰⁾, the response coefficient at the k-th iteration point w^{(k)} is obtained by solving the partial derivative of the functions (20) and (21) (note that in a real engineering environment, the response coefficients are obtained from excitation-response analysis as described at par. [0045]-[0065]):

$$\{ \begin{matrix}{c}_{1 , 1} = \frac{\partial {a}_{1}}{\partial {w}_{1}} = {w}_{2} \times {w}_{3} - 0.8 \times {w}_{1} \times {w}_{2}^{2} \times {w}_{3}^{2} \\ {c}_{2 , 1} = \frac{\partial {a}_{1}}{\partial {w}_{2}} = {w}_{1} \times {w}_{3} - 0.8 \times {w}_{1}^{2} \times {w}_{2} \times {w}_{3}^{2} \\ {c}_{3 , 1} = \frac{\partial {a}_{1}}{\partial {w}_{3}} = {w}_{1} \times {w}_{3} - 0.8 \times {w}_{1}^{2} \times {w}_{2}^{2} \times {w}_{3} \\ {c}_{1 , 2} = \frac{\partial {a}_{2}}{\partial {w}_{1}} = 0 \\ {c}_{2 , 2} = \frac{\partial {a}_{2}}{\partial {w}_{2}} = 0 \\ {c}_{3 , 2} = \frac{\partial {a}_{2}}{\partial {w}_{3}} = 1 - 0.8 \times {w}_{3}\end{matrix} \qquad ( 22 )$$

According to functional formula (16). the constraints of the linear programming of the k+1th iteration are expressed as follows:

$$\{ \begin{matrix}{c}_{1 , 1} \times Δ {w}_{1} + {c}_{2 , 1} \times Δ {w}_{2} + {c}_{3 , 1} \times Δ {w}_{3} \geq Δ {A}_{1} \\ {c}_{1 , 2} \times Δ {w}_{1} + {c}_{2 , 2} \times Δ {w}_{2} + {c}_{3 , 2} \times Δ {w}_{3} \geq Δ {A}_{2}\end{matrix} \qquad ( 23 )$$

The above formula c_{i,j} is the result value of w₁^{(k)}, w₂^{(k)}, w₃^{(k)} corresponding to the iterative point w^{(k)} into formula (22), Δwᵢ satisfies the constraint of formula (18), the definition of ΔAⱼ refers to (15) (16). Equations (19), (23), and (18) are the basic elements of the linear programming at the iteration point w^{(k+1)}, and iteratively approximates the optimal solution according to the description at par. [0085]-[0094].

Assuming A₁=0.4, A₂=0.3, the starting operating point is set to w₁⁽⁰⁾1, w₂⁽⁰⁾=1, w₃⁽⁰⁾=1, and the termination conditions σ=0.0001, λ=0.00001. The linear programming adopts Google's open-source optimization software suite-“or-tools”, and the iterative process is shown in Table 1:

TABLE 1

| k | progress* | δ | w₁ | w₂ | w₃ | E | a₁ | a₂ |
|---|---|---|---|---|---|---|---|---|
| 1 | 0% | 0.3000 | 1.0000 | 1.0000 | 1.0000 | 6.0000 | 0.6000 | 0.6000 |
| 2 | 58.6% | 0.3000 | 0.8500 | 0.8500 | 0.8500 | 5.1000 | 0.4633 | 0.5610 |
| 3 | | 0.3000 | 0.9779 | 0.7000 | 0.7000 | 4.4779 | 0.3873 | 0.5040 |
| 4 | | 0.3000 | 1.0000 | 0.8500 | 0.5642 | 4.3926 | 0.3876 | 0.4369 |
| 5 | | 0.3000 | 1.0000 | 0.8500 | 0.5666 | 4.3999 | 0.3889 | 0.4382 |
| 6 | | 0.1854 | 0.9779 | 0.7000 | 0.7000 | 4.4779 | 0.3873 | 0.5040 |
| 7 | | 0.1854 | 1.0000 | 0.7927 | 0.6215 | 4.4499 | 0.3956 | 0.4670 |
| 8 | | 0.1854 | 1.0000 | 0.7927 | 0.6231 | 4.4547 | 0.3964 | 0.4678 |
| 9 | 99.1% | 0.1146 | 0.9779 | 0.7000 | 0.7000 | 4.4779 | 0.3873 | 0.5040 |
| 10 | | 0.1146 | 1.0000 | 0.7573 | 0.6569 | 4.4853 | 0.3985 | 0.4843 |
| 11 | | 0.1146 | 1.0000 | 0.8146 | 0.6105 | 4.4608 | 0.3984 | 0.4614 |
| 12 | | 0.1146 | 1.0000 | 0.8146 | 0.6110 | 4.4621 | 0.3986 | 0.4617 |
| 13 | 98.6% | 0.0708 | 1.0000 | 0.7573 | 0.6569 | 4.4853 | 0.3985 | 0.4843 |
| 14 | 99.3% | 0.0708 | 1.0000 | 0.7927 | 0.6295 | 4.4740 | 0.3994 | 0.4710 |
| 15 | | 0.0708 | 1.0000 | 0.8281 | 0.6062 | 4.4641 | 0.3994 | 0.4574 |
| 16 | | 0.0708 | 1.0000 | 0.8635 | 0.5780 | 4.4611 | 0.3995 | 0.4444 |
| 17 | | 0.0708 | 1.0000 | 0.8635 | 0.5781 | 4.4613 | 0.3995 | 0.4444 |
| 18 | 100% | 0.0438 | 1.0000 | 0.8281 | 0.6026 | 4.4641 | 0.3994 | 0.4574 |
| 19 | 100% | 0.0438 | 1.0000 | 0.8500 | 0.5879 | 4.4636 | 0.3998 | 0.4496 |

*“progress” = (E^{(k)} − E⁽¹⁾)/(E^{(finish)} − E⁽¹⁾) × 100%, finish = 19ₜₕ in this table

The above “progress” column only fills in valid steps, and some iterations are invalid (go back), for example, in steps 3-5, since E⁽⁵⁾>E⁽⁴⁾, it indicates that “the objective function value changes in reverse”, so, return to the working state w⁽³⁾(go back 2 steps), and re-solve in the reduced adjacent area(reduced δ), which is the 6-th step it can also be seen from the table that w⁽⁶⁾=w⁽³⁾, δ⁽⁶⁾21 δ⁽³⁾. Others such as steps 6-8, 10-12, etc., are also voided (returned) for the same reason.

a₁⁽³⁾-a₁⁽⁹⁾ deviates non-negligible from the set A₁, and then gradually gets better. This is because the δ in the first few steps is large, which leads to a relatively large distance between w^{(k)} and the optimal solution w^{(k+1)} at the tangent plane of w^{(k)}. Although w^{(k+1)} is in compliance with the constraints in the tangent plane, it deviates when it is substituted into the working curved surface. When the optimal solution is gradually approached, the taken δ is also gradually reduced. In this local area, the point value on the tangent plane and the point value on the working curved surface are finally unified.

From the point of view of the iterative process, the convergence speed of this method is relatively fast, and after a few iterations, 99% of the final goal can be achieved. Note that also iteration with different initial values of δ (0.1, 0.2 . . . 0.6) is performed. The iterative accuracy and efficiency are not sensitive to the initial value of 6, which also proves that this solution is stable and reliable.

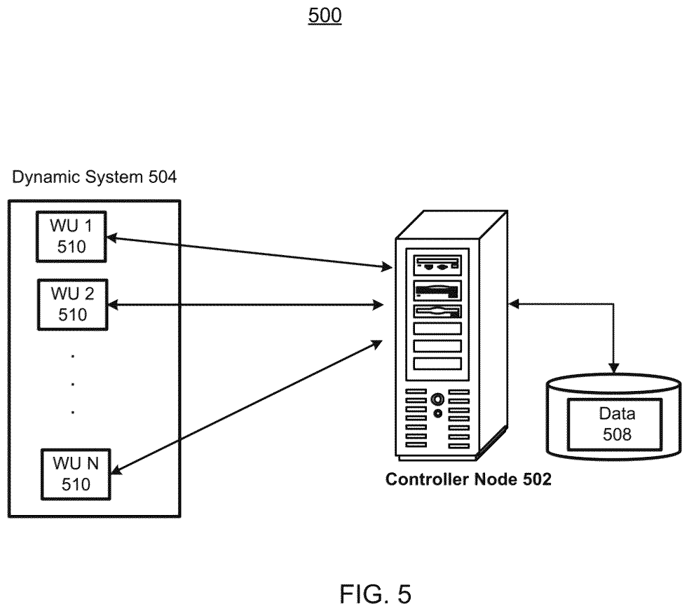

FIG. 5 illustrates a network for optimization of a dynamic system composed of multiple work units.

As shown in FIG. 5, the dynamic system 504 has n controllable working units 510. By adjusting the working states of these working units by the controller node 502 connected to these working units, the output states can be changed to achieve multiple groups of set goals.

Each working unit 510 may consume resources such as water, electricity, gas, fuel, cooling, or heat energy, etc. and may conduct energy conversion and transmission to achieve the set goals as output. In this example, control variables and dependent variables that are functions of working units 510 and can be collected in real time by the controller node 502. There may be multiple resource consumption of the working units 510 of the dynamic system 504. Different types of resources should be normalized into a unified unit. For instance, if the goal is an efficient operation (i.e., saving money), it should be normalized into a monetary unit and if the goals is reducing carbon emission, it should be normalized into carbon emission units.

As discussed above, each component of set goals can be in different units. For example, the output requirements of a system are: (a) the temperature (T) of the water tank is constant at 20° C.; (b) the output water flow is 1 m³/min. Two units involved here are T° C. and m³/min respectively. The basic task of the dynamic system optimization is to select a set of working states to minimize the aggregated consumed resources under the condition of satisfying the set goals. Note that the controller node 502 may be connected to the dynamic system 504 being optimized over a network. In one embodiment, the dynamic system 504 may have an integrated controller unit. The controller node 502 may be also connected to a data storage for string optimization parameter data 508 for future references.

As discussed above, a response matrix may be constructed by the controller node 502 superimposing periodic excitations of the dynamic system 504 at the input and detecting its output in real time. Based on the response matrix, linear programming may be applied and executed on the controller node 502 to solve the optimal working parameters in the vicinity of this work point. The optimal working state can be iteratively approached step-by-step.

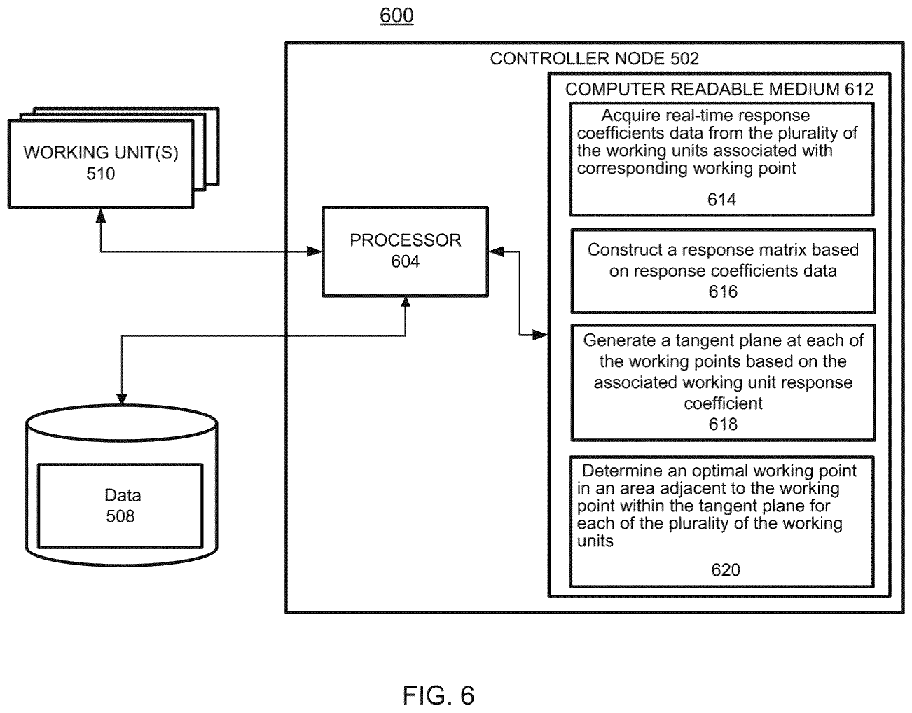

FIG. 6 illustrates a network diagram of a system 600 including a detailed description of a controller node 502, according to example embodiments. The controller node 502 may include additional components and that some of the components described herein may be removed and/or modified without departing from a scope of the controller node 502 disclosed herein. The controller node 502 may be a computing device or a server computer, or the like, and may include a processor 604, which may be a semiconductor-based microprocessor, a central processing unit (CPU), an application specific integrated circuit (ASIC), a field-programmable gate array (FPGA), and/or another hardware device. Although a single processor 604 is depicted, it should be understood that the controller node 502 may include multiple processors, multiple cores, or the like, without departing from the scope of the controller node 502.

The controller node 502 may also include a non-transitory computer readable medium 612 that may have stored thereon machine-readable instructions executable by the processor 604. Examples of the machine-readable instructions are shown as 614-620 and are further discussed below. Examples of the non-transitory computer readable medium 612 may include an electronic, magnetic, optical, or other physical storage device that contains or stores executable instructions. For example, the non-transitory computer readable medium 612 may be a Random Access Memory (RAM), an Electrically Erasable Programmable Read-Only Memory (EEPROM), a hard disk, an optical disc, or other type of storage device.

The processor 604 may execute the machine-readable instructions 614 to acquire real-time response coefficients data from the plurality of the working units associated with corresponding working points. The processor 604 may execute the machine-readable instructions 616 to construct a response matrix based on response coefficients data. The processor 604 may execute the machine-readable instructions 618 to generate a tangent plane at each of the working points based on the associated working unit response coefficient. The processor 604 may execute the machine-readable instructions 620 to determine an optimal working point in an area adjacent to the working point within the tangent plane for each of the plurality of the working units.

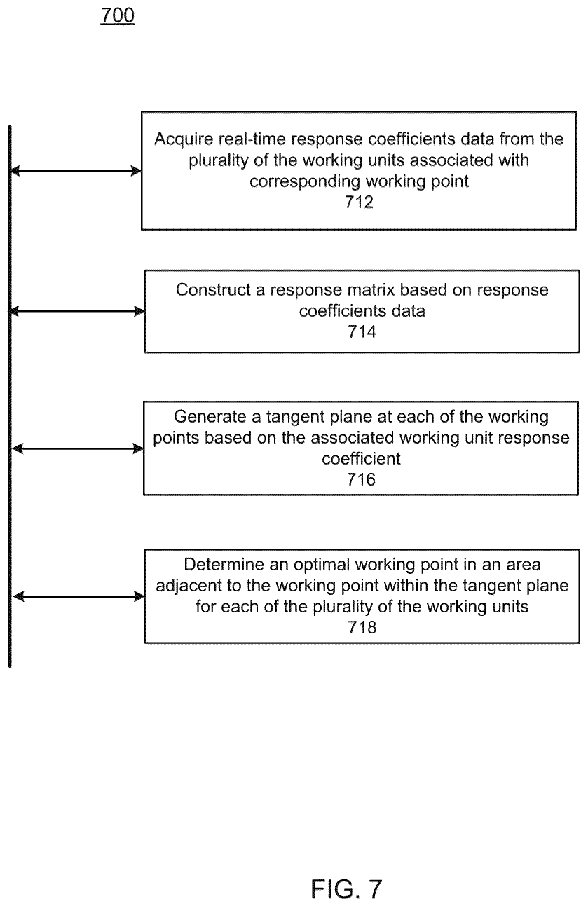

FIG. 7 illustrates a flow diagram 700 of an example method of optimization of a dynamic system with multiple controllable working units, according to example embodiments. Referring to FIG. 7, the method 700 may include one or more of the steps described below.

FIG. 7 illustrates a flow chart of an example method executed by the controller node 502 (see FIG. 6). It should be understood that method 700 depicted in FIG. 7 may include additional operations and that some of the operations described therein may be removed and/or modified without departing from the scope of the method 700. The description of the method 700 is also made with reference to the features depicted in FIG. 6 for purposes of illustration. Particularly, the processor 604 of the controller node 502 may execute some or all of the operations included in the method 700.

With reference to FIG. 7, at block 712, the processor 604 may acquire real-time response coefficients data from the plurality of the working units associated with corresponding working points. At block 714, the processor 604 may construct a response matrix based on response coefficients data. At block 716, the processor 604 may generate a tangent plane at each of the working points based on the associated working unit response coefficient. At block 718, the processor 604 may determine an optimal working point in an area adjacent to the working point within the tangent plane for each of the plurality of the working units.

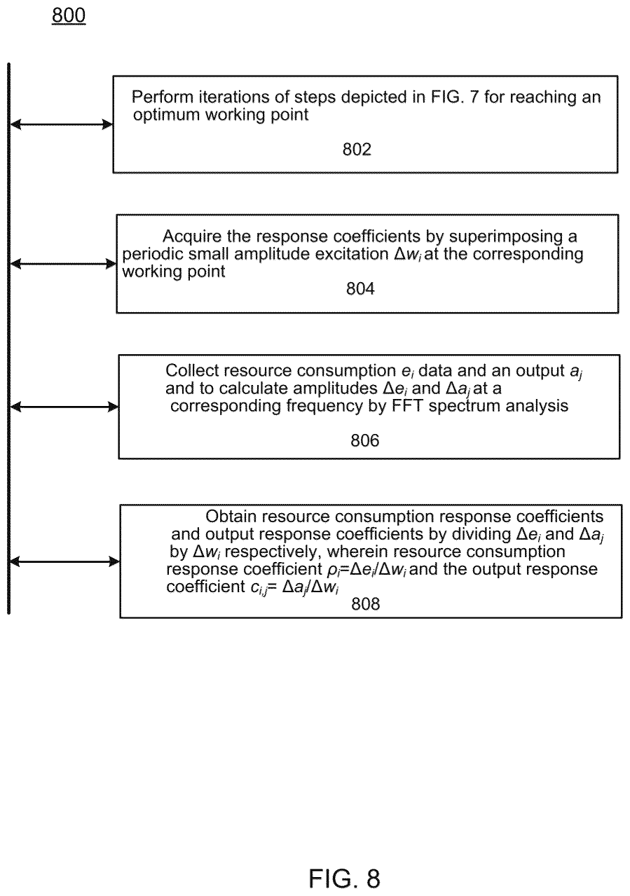

FIG. 8 illustrates a further flow diagram 800 of a method, according to example embodiments. Referring to FIG. 8, the method 800 may also include one or more of the following steps. At block 802, the processor 604 may perform iterations of steps depicted in FIG. 7 for reaching an optimum working point. At block 804, the processor 604 may acquire the response coefficients by superimposing a periodic small amplitude excitation Am, at the corresponding working point. At block 806, the processor 604 may collect resource consumption e, data and an output a 1 and to calculate amplitudes Ae, and Aa 1 at a corresponding frequency by FFT spectrum analysis. At block 808, the processor 604 may obtain resource consumption response coefficients and output response coefficients by dividing Δeᵢ and Δaⱼ by Δwᵢ respectively, wherein resource consumption response coefficient ρᵢ=Δeᵢ/Δwᵢ and the output response coefficient c_{i,j}=Δaⱼ/Δwᵢ.

The above embodiments may be implemented in hardware, in a computer program executed by a processor, in firmware, or in a combination of the above. A computer program may be embodied on a computer readable medium, such as a storage medium. For example, a computer program may reside in random access memory (“RAM”), flash memory, read-only memory (“ROM”), erasable programmable read-only memory (“EPROM”), electrically erasable programmable read-only memory (“EEPROM”), registers, hard disk, a removable disk, a compact disk read-only memory (“CD-ROM”), or any other form of storage medium known in the art.

An exemplary storage medium may be coupled to the processor such that the processor may read information from, and write information to, the storage medium. In the alternative, the storage medium may be integral to the processor. The processor and the storage medium may reside in an application specific integrated circuit (“ASIC”). In the alternative, the processor and the storage medium may reside as discrete components.

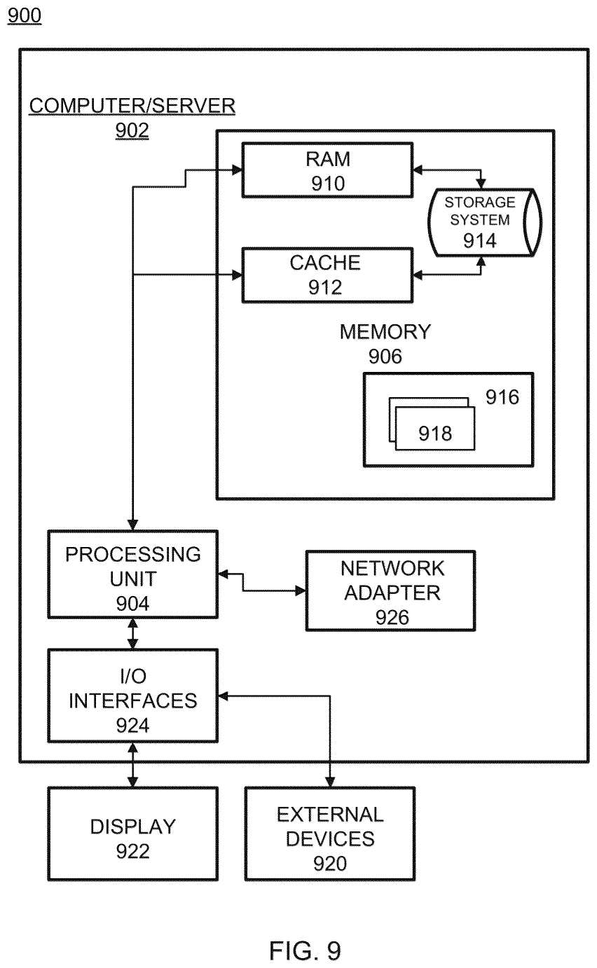

FIG. 9 illustrates an example controller node 900 that supports one or more of the example embodiments described and/or depicted herein. The controller node 900 comprises a computer system/server 902, which is operational with numerous other general purpose or special purpose computing system environments or configurations. Examples of well-known computing systems, environments, and/or configurations that may be suitable for use with computer system/server 902 include, but are not limited to, personal computer systems, server computer systems, thin clients, thick clients, hand-held or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

The computer system/server 902 may be described in the general context of computer system-executable instructions, such as program modules, being executed by a computer system. Generally, program modules may include routines, programs, objects, components, logic, data structures, and so on that perform particular tasks or implement particular abstract data types. Computer system/server 902 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 9, computer system/server 902 in the content processing node 900 is shown in the form of a general-purpose computing device. The components of computer system/server 902 may include, but are not limited to, one or more processors or processing units 904, a system memory 906, and a bus that couples various system components including system memory 906 to processor 904.

The bus represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 902 typically includes a variety of computer system readable media. Such media may be any available media that is accessible by computer system/server 902, and it includes both volatile and non-volatile media, removable and non-removable media. System memory 906, in one embodiment, implements the flow diagrams of the other figures. The system memory 906 can include computer system readable media in the form of volatile memory, such as random-access memory (RAM) 910 and/or cache memory 912. Computer system/server 902 may further include other removable/non-removable, volatile/non-volatile computer system storage media. By way of example only, storage system 914 can be provided for reading from and writing to a non-removable, non-volatile magnetic media (not shown and typically called a “hard drive”). Although not shown, a magnetic disk drive for reading from and writing to a removable, non-volatile magnetic disk, and an optical disk drive for reading from or writing to a removable, non-volatile optical disk such as a CD-ROM, DVD-ROM or other optical media can be provided. In such instances, each can be connected to the bus by one or more data media interfaces. As will be further depicted and described below, memory 906 may include at least one program product having a set (e.g., at least one) of program modules that are configured to carry out the functions of various embodiments of the application.

Program/utility 916, having a set (at least one) of program modules 918, may be stored in memory 906 by way of example, and not limitation, as well as an operating system, one or more application programs, other program modules, and program data. Each of the operating system, one or more application programs, other program modules, and program data or some combination thereof, may include an implementation of a networking environment. Program modules 918 generally carry out the functions and/or methodologies of various embodiments of the application as described herein.

As will be appreciated by one skilled in the art, aspects of the present application may be embodied as a system, method, or computer program product. Accordingly, aspects of the present application may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present application may take the form of a computer program product embodied in one or more computer readable medium(s) having computer readable program code embodied thereon.

Computer system/server 902 may also communicate with one or more external devices 920 such as a keyboard, a pointing device, a display 922, etc.; one or more devices that enable a user to interact with computer system/server 902; and/or any devices (e.g., network card, modem, etc.) that enable computer system/server 902 to communicate with one or more other computing devices. Such communication can occur via I/O interfaces 924. Still yet, computer system/server 902 can communicate with one or more networks such as a local area network (LAN), a general wide area network (WAN), and/or a public network (e.g., the Internet) via network adapter 926. As depicted, network adapter 926 communicates with the other components of computer system/server 902 via a bus. It should be understood that although not shown, other hardware and/or software components could be used in conjunction with computer system/server 902. Examples, include, but are not limited to: microcode, device drivers, redundant processing units, external disk drive arrays, RAID systems, tape drives, and data archival storage systems, etc.

Although an exemplary embodiment of at least one of a system, method, and non-transitory computer readable medium has been illustrated in the accompanied drawings and described in the foregoing detailed description, it will be understood that the application is not limited to the embodiments disclosed, but is capable of numerous rearrangements, modifications, and substitutions as set forth and defined by the following claims. For example, the capabilities of the system of the various figures can be performed by one or more of the modules or components described herein or in a distributed architecture and may include a transmitter, receiver or pair of both. For example, all or part of the functionality performed by the individual modules, may be performed by one or more of these modules. Further, the functionality described herein may be performed at various times and in relation to various events, internal or external to the modules or components. Also, the information sent between various modules can be sent between the modules via at least one of: a data network, the Internet, a voice network, an Internet Protocol network, a wireless device, a wired device and/or via plurality of protocols. Also, the messages sent or received by any of the modules may be sent or received directly and/or via one or more of the other modules.

One skilled in the art will appreciate that a “system” could be embodied as a personal computer, a server, a console, a personal digital assistant (PDA), a cell phone, a tablet computing device, a smartphone or any other suitable computing device, or combination of devices. Presenting the above-described functions as being performed by a “system” is not intended to limit the scope of the present application in any way but is intended to provide one example of many embodiments. Indeed, methods, systems and apparatuses disclosed herein may be implemented in localized and distributed forms consistent with computing technology.

It should be noted that some of the system features described in this specification have been presented as modules, in order to more particularly emphasize their implementation independence. For example, a module may be implemented as a hardware circuit comprising custom very large-scale integration (VLSI) circuits or gate arrays, off-the-shelf semiconductors such as logic chips, transistors, or other discrete components. A module may also be implemented in programmable hardware devices such as field programmable gate arrays, programmable array logic, programmable logic devices, graphics processing units, or the like.

A module may also be at least partially implemented in software for execution by various types of processors. An identified unit of executable code may, for instance, comprise one or more physical or logical blocks of computer instructions that may, for instance, be organized as an object, procedure, or function. Nevertheless, the executables of an identified module need not be physically located together but may comprise disparate instructions stored in different locations which, when joined logically together, comprise the module and achieve the stated purpose for the module. Further, modules may be stored on a computer-readable medium, which may be, for instance, a hard disk drive, flash device, random access memory (RAM), tape, or any other such medium used to store data.

Indeed, a module of executable code could be a single instruction, or many instructions, and may even be distributed over several different code segments, among different programs, and across several memory devices. Similarly, operational data may be identified and illustrated herein within modules and may be embodied in any suitable form and organized within any suitable type of data structure. The operational data may be collected as a single data set or may be distributed over different locations including over different storage devices, and may exist, at least partially, merely as electronic signals on a system or network.

It will be readily understood that the components of the application, as generally described and illustrated in the figures herein, may be arranged and designed in a wide variety of different configurations. Thus, the detailed description of the embodiments is not intended to limit the scope of the application as claimed but is merely representative of selected embodiments of the application.

One having ordinary skill in the art will readily understand that the above may be practiced with steps in a different order, and/or with hardware elements in configurations that are different than those which are disclosed. Therefore, although the application has been described based upon these preferred embodiments, it would be apparent to those of skill in the art that certain modifications, variations, and alternative constructions would be apparent.

While preferred embodiments of the present application have been described, it is to be understood that the embodiments described are illustrative only and the scope of the application is to be defined solely by the appended claims when considered with a full range of equivalents and modifications (e.g., protocols, hardware devices, software platforms etc.) thereto.

What is claimed is:

1. A system, comprising:
a processor of a controller node connected to a plurality of working units;
a memory on which are stored machine-readable instructions that when executed by the processor, cause the processor to:
(i) acquire real-time response coefficients data from the plurality of the working units associated with corresponding working points;
(ii) construct a response matrix based on response coefficients data;
(iii) generate a tangent plane at each of the working points based on the associated working unit response coefficient; and
(iv) determine an optimal working point in an area adjacent to the working point within the tangent plane for each of the plurality of the working units.

2. The system of claim 1, wherein the instructions further cause the processor to perform iterations of steps (ii)-(iv) for reaching an optimum working point.

3. The system of claim 1, wherein the instructions further cause the processor to acquire the response coefficients by superimposing a periodic small amplitude excitation Am, at the corresponding working point.

4. The system of claim 2, wherein the instructions further cause the processor to collect resource consumption e, data and an output a 1 and to calculate amplitudes Δeᵢ and Δaⱼ at a corresponding frequency by FFT spectrum analysis.

5. The system of claim 4, wherein the instructions further cause the processor to obtain resource consumption response coefficients and output response coefficients by dividing Δeᵢ and Δaⱼ by Δwᵢ respectively, wherein resource consumption response coefficient ρᵢ=Δeᵢ/Δwᵢ and the output response coefficient cᵢⱼ=Δaⱼ/Δwᵢ.

6. The system of claim 1, wherein the response coefficient is mathematically equivalent to a partial derivative of an output function at the working point.

7. The system of claim 3, wherein the amplitude excitation Δwᵢ is realized by periodically adding or subtracting a small amount Δwᵢ on wᵢ, or by periodically changing its duty cycle by a PWM method.

8. The system of claim 1, wherein the response matrix is composed of response coefficients is configured to express sensitivity of an output at the working point to a change of a working state.

9. The system of claim 1, wherein the tangent plane is a tangent plane at the working point of a working surface in a multi-dimensional space, wherein an optimization process at the working point is transformed into a linear programming process in the tangent plane.

10. The system of claim 1, wherein the adjacent area is an adjacent area of the working point w^{(k)} in the tangent plane, wherein a range of the adjacent area Δw^{(k+1)} ensures that any value in the adjacent area satisfies a condition w^{k+1)}=w^{(k)}+Δw^{k+1)} in a region w.

11. The system of claim 2, wherein if during the iteration resource consumption changes in reverse, a range of a neighboring area is reduced to approach an optimal working point in smaller steps, wherein the iteration comprises going back two steps to start from a previous working point w^{(k+1)} for subsequent iterations.

12. The system of claim 2, wherein a termination condition for the iteration is any of:
a difference between resource consumption of two consecutive working points w^{(k)} and w^{(k+1)} is less than a set value; and
a step size between two consecutive operating points w^{(k)} and w^{(k+1)} is less than a set value.

13. A method, comprising:
acquiring, by a controller node, real-time response coefficients data from a plurality of the working units associated with corresponding working points;
(ii) constructing, by the controller node, a response matrix based on response coefficients data;
(iii) generating, by the controller node, a tangent plane at each of the working points based on the associated working unit response coefficient; and
(iv) determining an optimal working point in an area adjacent to the working point within the tangent plane for each of the plurality of the working units.

14. The method of claim 13, further comprising performing iterations of steps (ii)-(iv) for reaching an optimum working point.

15. The method of claim 13, further comprising acquiring the response coefficients by superimposing a periodic small amplitude excitation Δwᵢ at the corresponding working point.

16. The method of claim 15, further comprising collecting resource consumption e, data and an output aⱼ data and calculating amplitudes Δeᵢ and Δaⱼ at a corresponding frequency by FFT spectrum analysis.

17. The method of claim 16, further comprising obtaining resource consumption response coefficients and output response coefficients by dividing Δeᵢ, and Δaⱼ by Δwᵢ respectively, wherein resource consumption response coefficient ρᵢ=Δeᵢ/Δwᵢ and the output response coefficient c_{i,j}=Δaⱼ/Δwᵢ.

18. A non-transitory computer readable medium comprising instructions, that when read by a processor, cause the processor to perform:
acquiring real-time response coefficients data from a plurality of the working units associated with corresponding working points;
constructing a response matrix based on response coefficients data;
generating a tangent plane at each of the working points based on the associated working unit response coefficient; and
determining an optimal working point in an area adjacent to the working point within the tangent plane for each of the plurality of the working units.

19. The non-transitory computer readable medium of claim 18, further comprising instructions, that when read by the processor, cause the processor to collect resource consumption e, data and an output aⱼ data and calculating amplitudes Δeᵢ, and Δaⱼ at a corresponding frequency by FFT spectrum analysis.

20. The non-transitory computer readable medium of claim 19, further comprising instructions, that when read by the processor, cause the processor to obtain resource consumption response coefficients and output response coefficients by dividing Δeᵢ and Δaⱼ by Δwᵢ respectively, wherein resource consumption response coefficient ρᵢ=Δeᵢ/Δwᵢ and the output response coefficient c_{i,j}=Δaⱼ/Δwᵢ.
